(19) United States
(12) Patent Application Publication
(10) Pub. No.: US 2026/0066233 A1
(43) Pub. Date: Mar. 5, 2026

(54) Multi-Spoke Shield for a Process Chamber

(71) Applicant: Applied Materials, Inc., Santa Clara, CA (US)

(72) Inventors: Yang YANG, Cupertino, CA (US); Kartik RAMASWAMY, San Jose, CA (US); Fernando SILVEIRA, Livermore, CA (US); Yue GUO, Redwood City, CA (US); A N M Wasekul AZAD, Cupertino, CA (US); Yuhui ZHANG, Sunnyvale, CA (US); Zhimin JIANG, Santa Clara, CA (US)

(21) Appl. No.: 18/823,571

(22) Filed: Sep. 3, 2024

(51) Int. Cl. H01J 37/32

(52) U.S. Cl. CPC H01J 37/3244; H01J 37/32522; H01J 37/321; H01J 2237/002

(57) ABSTRACT

Embodiments of apparatus for use in a process chamber are provided herein. In some embodiments, an apparatus for use in a process chamber includes an annular body having one or more annular plenums disposed therein and an upper surface configured to be coupled to a lid of the process chamber; a plurality of spokes extending radially inward from the annular body toward a central axis of the annular body; and a plurality of gas outlets disposed along different radial locations of each spoke of the plurality of spokes, wherein the plurality of gas outlets are fluidly coupled to the one or more annular plenums.

### FIELD

Embodiments of the present disclosure generally relate to substrate processing equipment.

### BACKGROUND

With technology node advancing towards sub-nm sizes, the fabrication of complicated 3D structures produces unprecedented challenges for the uniformity control of etching and deposition processes. Traditional inductively coupled plasma etchers only have center gas injection and edge gas injection around the chamber wall of the plasma etcher. The inventors believe that such an arrangement works for processes with etch stop layers, but can no longer meet the requirements for cutting-edge manufacturing methods. Moreover, the inventors have observed that for inductively coupled plasma etchers, lid sputtering and associated particle generation, due to capacitive coupling between the lid and a coil disposed outside of a chamber body, cause productivity issues and limits process yield and part lifetime. A Faraday shield is typically used outside of the chamber body and between the coil and a ceramic lid to reduce the capacitive coupling effect, thereby minimizing lid sputtering. However, as power increases, the chamber shield could be a potential risk for arcing and any prevention effort increases design and installation difficulties.

Accordingly, the inventors have provided herein embodiments of improved apparatus for reducing capacitive coupling or arcing between a lid and a coil.

### SUMMARY

Embodiments of apparatus for use in a process chamber are provided herein. In some embodiments, an apparatus for use in a process chamber includes an annular body having one or more annular plenums disposed therein and an upper surface configured to be coupled to a lid of the process chamber; a plurality of spokes extending radially inward from the annular body toward a central axis of the annular body; and a plurality of gas outlets disposed along different radial locations of each spoke of the plurality of spokes, wherein the plurality of gas outlets are fluidly coupled to the one or more annular plenums.

In some embodiments, an apparatus for use in a process chamber includes an annular body having one or more annular plenums disposed therein and an upper surface configured to be coupled to a lid of the process chamber; a plurality of spokes extending radially inward from the annular body toward a central axis of the annular body; and a plurality of gas outlets disposed along different radial locations of each spoke of the plurality of spokes, wherein the plurality of gas outlets are fluidly coupled to the one or more annular plenums, wherein each spoke of the plurality of spokes includes one or more injection channels extending radially from the annular body toward the central axis and the plurality of gas outlets extend from the one or more injection channels to a lower surface of each spoke; wherein the one or more annular plenums comprise two annular plenums that are separated by a divider wall, wherein an upper plenum of the two annular plenums is fluidly coupled to a first set of the plurality of spokes and a lower plenum of the two annular plenums is fluidly coupled to a second set of the plurality of spokes different than the first set; and wherein at least one of: a heater disposed in the plurality of spokes; or a cooling channel disposed in the plurality of spokes.

In some embodiments, a process chamber includes: a chamber body having sidewalls and a lid to define an interior volume therein, wherein the lid includes a central opening; a substrate support for supporting a substate disposed in the interior volume; and an apparatus disposed in the interior volume adjacent to the lid, the apparatus comprising: an annular body having one or more annular plenums disposed therein and an upper surface configured to be coupled to a lid of the process chamber, wherein the annular body is made of a metal material and configured to form a faraday cage; a plurality of spokes extending radially inward from the annular body toward a central axis of the annular body; and a plurality of gas outlets disposed along different radial locations of each spoke of the plurality of spokes, wherein the plurality of gas outlets are fluidly coupled to the one or more annular plenums.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a process chamber in accordance with at least some embodiments of the present disclosure.

FIG. 2 depicts an isometric top view of multi-spoke shield in accordance with at least some embodiments of the present disclosure.

FIG. 3 depicts a partial cross-sectional isometric top view of a multi-spoke shield in accordance with at least some embodiments of the present disclosure.

FIG. 4 depicts a schematic side view of a portion of a spoke in accordance with at least some embodiments of the present disclosure.

FIG. 5 depicts a cross-sectional side view of a portion of a multi-spoke shield in accordance with at least some embodiments of the present disclosure.

FIG. 6 depicts a schematic cross-sectional view of a spoke in accordance with at least some embodiments of the present disclosure.

FIG. 7 depicts a schematic cross-sectional view of a spoke in accordance with at least some embodiments of the present disclosure.

FIG. 8 depicts a schematic cross-sectional view of a spoke in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of an apparatus for reducing capacitive coupling or arcing between a lid and a coil of a process chamber are provided herein. The apparatus generally includes an annular body and a plurality of spokes extending radially inward from the annular body. The apparatus is disposed within an interior volume (i.e., plasma side) of the process chamber to advantageously provide faraday shielding and proximate the lid to reduce or prevent arcing. For example, the whole apparatus is grounded by ohmic contact with a grounded chamber body or grounded by cable. Installation of the apparatus on the plasma side provides a lower voltage on the lid compared to conventional methods thereby reducing sputtering damage because the ground is closer to plasma.

The apparatus may also advantageously function as a showerhead and provide additional benefits. For example, the showerhead may provide gas injection via the plurality of spokes across a substrate for enhanced process uniformity control. The apparatus may also advantageously provide radical injection, via the plurality of spokes, for enhanced process uniformity control. The apparatus may also advantageously be configured for temperature control to provide enhanced process uniformity, for example, by including heating elements and/or cooling channels.

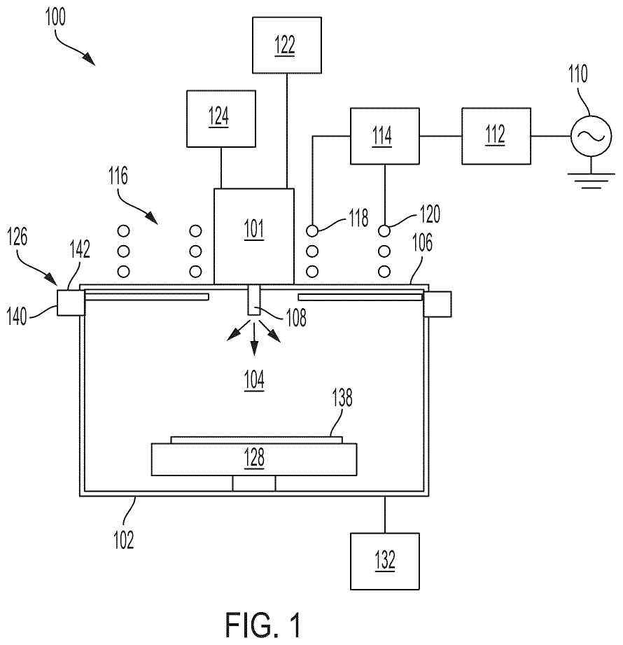

FIG. 1 depicts a schematic side view of a process chamber 100 in accordance with at least some embodiments of the present disclosure. The process chamber 100 can be utilized alone or as a processing module of an integrated semiconductor substrate processing system (e.g., a cluster tool). Examples of suitable process chambers that may advantageously benefit from modification in accordance with embodiments of the present disclosure include plasma process chambers, such as capacitively or inductively coupled plasma process chambers (ICP chambers). Exemplary plasma process chambers include etch reactors, CVD reactors, substrate plasma treatment reactors, and the like.

The process chamber 100 generally includes a chamber body 102 and a lid 106 that together define an interior volume 104. A substrate support 128 is disposed within the interior volume 104. The substrate support 128 includes a support surface for supporting a substrate 138. The process chamber 100 can optionally include an inductive or capacitive plasma source. In the embodiment depicted in FIG. 1, an inductive plasma source is provided, including one or more electrodes (e.g., conductive coils 116) disposed proximate the lid 106. In such an embodiment, the lid 106 is dielectric and the chamber body 102 is conductive. The one or more conductive coils 116 can be disposed above the lid 106 and are configured to inductively couple RF energy into the interior volume 104.

In some embodiments, the inductive plasma source includes an RF feed structure for coupling an RF source 110 (e.g., a second RF source) to the one or more conductive coils 116, e.g., a first conductive coil 118 and a second conductive coil 120. The one or more conductive coils are coaxially disposed proximate the process chamber 100 (for example, above the lid 106 of the process chamber 100) and are configured to inductively couple RF energy into the interior volume 104 to form or control a plasma from process gases provided within the interior volume 104 via a gas source 122. The gas source 122 can be coupled to the interior volume 104 via a gas inlet disposed in a central opening of the lid 106, or via other locations. A remote plasma apparatus (e.g., the remote plasma apparatus 101) is coupled to the chamber body 102 or the lid 106. A gas outlet of the remote plasma apparatus 101 may function as, or be in direct fluid communication with, a showerhead or a nozzle 108. A vacuum source 132 may be coupled to the chamber body 102 to exhaust the interior volume 104 and/or control a pressure of the interior volume 104.

The RF source 110 may be coupled to the RF feed structure via a match network 112. A power divider 114 may be provided to adjust the RF power respectively delivered to the first conductive coil 118 and the second conductive coil 120. The power divider 114 may be coupled between the match network 112 and the RF feed structure or may be a part of the match network 112. The RF source 110 may be capable of producing sufficient power at a tunable frequency within a range from about 400 kHz to about 10,000 GHz, or from about 400 kHz to about 13.56 MHz, although other frequencies and powers may be provided as desired for particular applications. In some embodiments, the RF source 110 may be provided at powers greater than about 10 KW.

The remote plasma apparatus 101 is coupled to an RF source 124 in any of the ways discussed above. The remote plasma apparatus 101 has a resonance at a frequency proximate to the frequency of the RF source 124. In some embodiments, the RF source 124 has a different frequency than the RF source 110, advantageously limiting a parasitic load on the RF source 110 from the remote plasma apparatus 101. In embodiments, the RF frequency of the RF source 124 is higher than the RF frequency of the RF source 110. In some embodiments, the RF frequency of the RF source 124 is lower than the RF frequency of the RF source 110.

A multi-spoke shield 126 is disposed in the interior volume 104 and adjacent to the lid 106. The multi-spoke shield 126 may be disposed between the chamber body 102 and the lid 106. The multi-spoke shield 126 generally comprises an annular body 140 having one or more annular plenums 142 disposed therein. The annular body 140 may be made of a metal or conductive material, such as aluminum. The multi-spoke shield 126 advantageously may form a faraday shield, or faraday cage, when installed, reducing or preventing sputtering caused by one or more of the RF source 110 and RF source 124. In some embodiments, where the function of a faraday shield is not needed, the multi-spoke shield 126 may be made of a ceramic material.

In some embodiments, an inner diameter of the annular body 140 is at least 1 inch away (projected on a horizontal plane) from an outer diameter of the outmost turn of the conductive coils 116 to avoid generation of eddy current. In some embodiments, the surfaces of the multi-spoke shield 126 in contact with plasma or radicals or reactive gases should be coated with a protective inert layer or anodized.

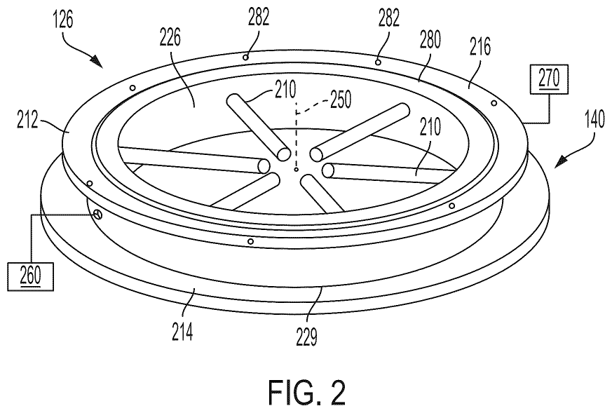

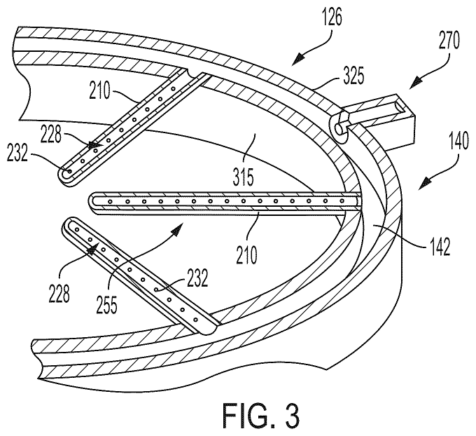

FIG. 2 depicts an isometric top view of a multi-spoke shield 126 in accordance with at least some embodiments of the present disclosure. FIG. 3 depicts a partial cross-sectional isometric top view of a multi-spoke shield 126 in accordance with at least some embodiments of the present disclosure. The multi-spoke shield 126 includes the annular body 140 and a plurality of spokes 210 extending radially inward from the annular body 140 toward a central axis 250 of the annular body 140.

The annular body 140 includes one or more annular plenums 142 disposed therein. The annular body 140 includes an upper surface 216 configured to be coupled to the lid 106 of the process chamber 100. The annular body 140 may comprise an inner wall 315 and an outer wall 325, with the one or more annular plenums 142 disposed therebetween. The plurality of spokes 210 may extend from the inner wall 315.

A seal 280, such as an o-ring, may be disposed on the upper surface 216 to form a seal between the annular body 140 and the lid 106. In some embodiments, the annular body 140 includes an upper flange 212 extending from the upper surface 216 of the annular body 140. In some embodiments, the annular body 140 includes a lower flange 214 extending from a lower surface 229 of the annular body 140. In some embodiments, the upper flange 212 includes one or more fastener openings 282 to facilitate fastening the upper flange 212 to the lid 106. In some embodiments, the lower flange 214 is coupled to the chamber body 102.

A plurality of spokes 210 extend radially inward from an inner surface 226 of the annular body 140. In some embodiments, a plurality of gas outlets 232 are disposed along of each spoke of the plurality of spokes 210. In some embodiments, each spoke of the plurality of spokes 210 has an injection channel 228 extending radially from the annular body 140 toward the central axis 250. In some embodiments, the plurality of gas outlets 232 extend from the injection channel 228 to a lower surface 255 of each spoke. In some embodiments, a process gas source 260 is fluidly coupled to the one or more annular plenums 142. In some embodiments, the process gas source 260 is the gas source 122. In some embodiments, the process gas source 260 is different than the gas source 122.

In some embodiments, a radical generation source 270 is fluidly coupled to the one or more annular plenums 142. The radical generation source 270 is configured to generate radicals that are injected through at least some of the plurality of gas outlets 232. The plurality of gas outlets 232 may be fluidly coupled to the one or more annular plenums 142 to provide process gas (e.g., from the process gas source 260) or radicals (e.g., from the radical generation source 270) to the plurality of gas outlets 232 via the one or more annular plenums 142. In some embodiments, multiple ones of the radical generation source 270 may be disposed about the annular body 140.

In some embodiments, plasma facing surfaces of the multi-spoke shield 126 may be coated with a ceramic material or anodized. In some embodiments, an outer surface of the plurality of spokes 210 is coated with a ceramic material or is anodized. In some embodiments, the coating comprises an alumina and yttria based ceramic material which is resistant to reactive gases. The coating thickness ranges from a few mils to thousands of mils.

In some embodiments, the plurality of spokes 210 are uniformly spaced around the annular body 140. In some embodiments, the plurality of spokes 210 have a circular or rectangular cross-sectional shape. If circular, the diameter of the spokes may be between about 0.1 inches to about 1.5 inches. If rectangular, the height of the spokes can be about 0.1 inches to about 1 inches. If rectangular, the width of the spokes can be about 0.1 inches to about 2 inches. The number of spokes of the plurality of spokes 210 can be, for example, between about 4 to about 20 spokes.

The number, spacing and diameter of the plurality of gas outlets 232 may be provided in any suitable arrangement to achieve best uniformity. For example, the spacing between gas outlets could be decreased or increased radially. In some embodiments, a diameter of the plurality of gas outlets 232 is generally less than about 60 mil to avoid plasma light up. The plurality of gas outlets 232 may be arranged in a single row (as shown in FIG. 3) or be arranged in multiple rows.

The plurality of spokes 210 can be grouped and the one or more annular plenums 142 can correspond with a plenum for gas injection and another plenum for radical injection. For example, the annular body 140 can be divided into an upper plenum and a lower plenum with separation in between (discussed in more detail below). As depicted in FIG. 2, if the plurality of spokes 210 comprise 6 spokes in total, the upper plenum could connect to spokes 1, 3 and 5 for gas injection and the lower plenum could connect to spokes 2, 4 and 6 for radical injection. Gas injection and radical injection can be implemented at the same time, or at different times.

The radical generation source 270 may be any suitable remote plasma source (based on inductive coupling, capacitively coupling, microwave coupling, surface wave coupling, electron cyclotron resistance (ECR), helicon, or the like) for radical generation. In some embodiments, an embedded RF electrode or coil can be used inside the annular body 140 for radical generation. In such embodiments, the plasma can be generated inside the annular body 140. Since the diameter of the plurality of gas outlets 232 is smaller than a plasma sheath thickness, the plasma is prevented from entering the plurality of gas outlets 232, effectively allowing only radicals/gases to be injected into the interior volume 104.

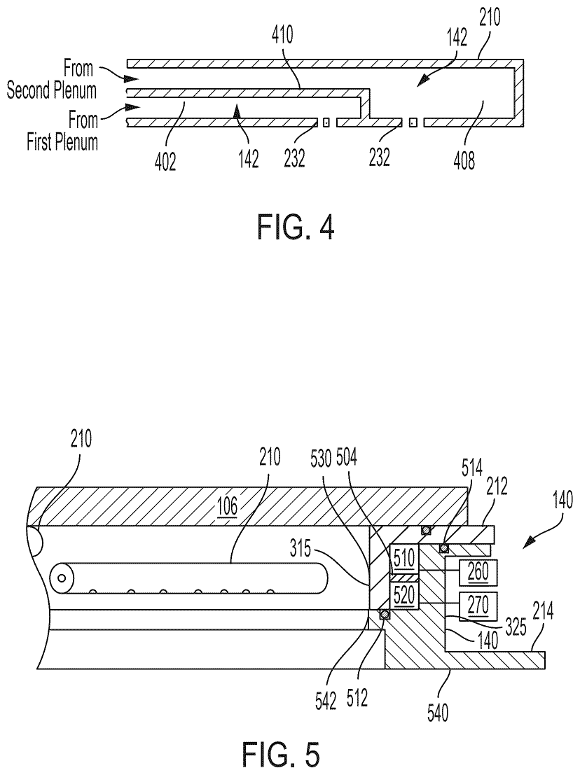

FIG. 4 depicts a schematic side view of a portion of a spoke of the plurality of spokes 210 in accordance with at least some embodiments of the present disclosure. In some embodiments, the spokes can be made of nested tubes or groups of tubes so different radial gas/radical injection zones can be defined, for example, an inner zone and outer zone. In doing so, the plurality of spokes 210 can be configured to have different flow ratio control radially.

In some embodiment, the one or more injection channels comprise a gas injection channel and a radical injection channel separate from the gas injection channel. In some embodiments, the one or more annular plenums 142 comprise a first plenum (e.g., first plenum 510) and a second plenum (e.g., second plenum 520), and as shown in FIG. 4, the injection channel 228 includes a separation wall 410 that defines an inner injection zone 402 and an outer injection zone 408 that is fluidly independent of the inner injection zone 402 within each spoke. The plurality of gas outlets 232 disposed along the inner injection zone 402 are fluidly coupled to the first plenum and the plurality of gas outlets 232 disposed along the outer injection zone 408 are fluidly coupled to the second plenum. In some embodiments, the inner injection zone 402 may be for inner gas injection from the process gas source 260 or inner radical injection from the radical generation source 270. In some embodiments, the outer injection zone 408 may be for outer gas injection from the process gas source 260 or outer radical injection from the radical generation source 270.

The length of each injection zone can be a suitable length to provide process uniformity. For example, the inner injection zone 402 may extend from a first side of the spoke adjacent the annular body 140 to a distance of about 10 cm. In some embodiments, the outer injection zone 408 may extend from about 10 cm to about 20 cm from the first side of the spoke. In some embodiments, all inner and outer surfaces of the plurality of spokes 210 that are in contact with plasma, radicals, or process gases are coated with a ceramic material or is anodized, as discussed above.

FIG. 5 depicts a cross-sectional side view of a portion of a multi-spoke shield 126 in accordance with at least some embodiments of the present disclosure. The plurality of spokes 210 are disposed between an upper surface and a lower surface of the annular body 140. In some embodiments, the plurality of spokes 210 are in contact with the lid 106 to reduce or prevent sputtering from plasma ion bombardment. In some embodiments, the one or more annular plenums 142 comprise a first plenum 510 and a second plenum 520 that are separated by a divider wall 504. The divider wall 504 may extend from the inner wall 315 to the outer wall 325 of the annular body 140 to define the first plenum 510, or upper plenum, and the second plenum 520, or lower plenum. The first plenum 510 may be fluidly coupled to a first set of the plurality of spokes 210 and the second plenum 520 is fluidly coupled to a second set of the plurality of spokes 210 different than the first set. In some embodiments, the first set and the second set may comprise alternating ones of the plurality of spokes 210.

In some embodiments, the annular body 140 comprises a first component 530 and a second component 540 disposed radially outward of the first component 530. In some embodiments, the first component 530 comprises the inner wall 315 and the upper flange 212 extending radially outward from the inner wall 315. In some embodiments, the second component 540 comprises the outer wall 325 and the lower flange 214 extending radially outward from the outer wall 325. The second component 540 may further include an inner lip 542 extending radially inward from the outer wall 325. The first component 530 may be coupled to the second component 540 with the first component 530 resting on an upper surface of the inner lip 542 and an upper surface of the outer wall 325. In some embodiments, a first seal 512 is disposed between the inner lip 542 and the inner wall 315. In some embodiments, a second seal 514 is disposed between the outer wall 325 and the upper flange 212. The first component 530 and the second component 540 may define the one or more annular plenums 142 therebetween. In some embodiments, the lower flange 214 extends radially outward beyond the upper flange 212.

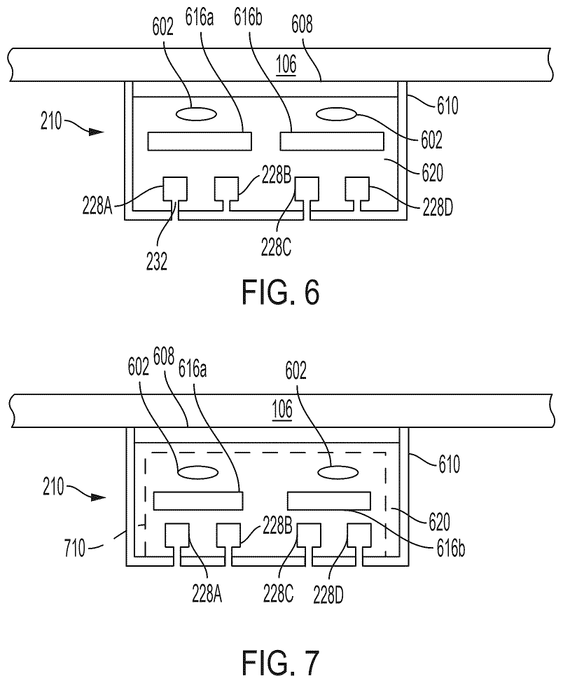

FIG. 6 depicts a schematic cross-sectional view of a spoke of the plurality of spokes 210 in accordance with at least some embodiments of the present disclosure. For high volume production, tight control of the temperature of any surfaces in contact with plasma is necessary for repeatability and reliability. In some embodiments, the plurality of spokes 210 include heating elements and/or cooling channels integrated therein. In some embodiments, the plurality of spokes 210 are bonded to the lid 106, via a bonding layer 608, for maximizing heat transfer. In such amendments, the lid 106 and the multi-spoke shield 126 may comprise a single part. In doing so, the temperature of the multi-spoke shield structure as well as the lid 106 are well controlled to prevent thermal-run-away.

In some embodiments, the plurality of spokes 210 include one or more heaters 602 that, for example, comprise resistive heating elements such as resistive wires. In some embodiments, the plurality of spokes 210 include one or more cooling channels 616 disposed in the plurality of spokes 210. For example, the one or more cooling channels 616 may include a supply channel 616a extending radially inward toward the central axis 250 and a return channel 616b extending radially outward away from the central axis 250 back to the annular body 208. The one or more cooling channels 616 could be used to flow air, compressed air, helium, or any other suitable liquid for effective cooling.

In some embodiments, the plurality of spokes 210 include separate channels for gas and radical injection, for inner and outer zones, respectively. For example, the injection channel 228 includes a first channel 228A for supply to the inner injection zone and a second channel 228B for supply to the outer injection zone. The first channel 228A and the second channel 228B may be for injecting a first process gas or radicals. In some embodiments, the injection channel 228 includes a third channel 228C for supply to the inner injection zone and a fourth channel 228D for supply to the outer injection zone. The third channel 228C and the fourth channel 228D may be for injecting the first process gas, a second process gas, or radicals. In some embodiments, a group of the injection channels 228, for example, the first channels 228A of all of the plurality of spokes 210, may be fluidly coupled to one of the one or more annular plenums 142. In some embodiments, the injection channel 228 may comprise channels arranged into groups, such as the first channel 228A of each spoke of the plurality of spokes 210, the second channel 228B of each spoke, the third channel 228C of each spoke, the fourth channel 228D of each spoke, and the like. Each of the groups of channels can be coupled to corresponding or associated ones of the one or more annular plenums 142. In some embodiments, one or more of the groups of channels of the injection channels 228 may be connected with a gas line that extends to a flange that routes the channels to the annular plenums. In the example above, with four such groups of injection channels, the one or more annular plenums 142 may comprise four annular plenums. In some embodiments, the four annular plenums may be associated with an inner gas injection zone, an outer gas injection zone, an inner radical injection zone, and an outer radical injection zone.

The injection channel 228 may have any suitable cross-sectional shape, for example, rectangular, circular, elliptical, or the like. In some embodiments, the first process gas is nitrogen trifluoride (NF₃). In some embodiments, the second process gas is ammonia (NH₃). In some embodiments, all the surfaces in contact with plasma or radicals or reactive gases are coated as discussed above. For example, the plurality of spokes 210 may comprise a body 620 made of metal covered with a coating layer 610 made of, for example, a ceramic material.

FIG. 7 depicts a schematic cross-sectional view of a spoke of the plurality of spokes 210 in accordance with at least some embodiments of the present disclosure. If the injection channel 228 or one or plurality of gas outlets 232 are too small, thereby prohibiting effective coating, then the body 620 can be made of ceramic, such as alumina (Al₂O₃), aluminum nitride (AlN), or other suitable material. To prevent sputtering, in some embodiments, the plurality of spokes 210 comprise the body 620 made of ceramic and a metal mesh 710 disposed in the body 620 made of ceramic. The metal mesh 710 is grounded to work as a Faraday shield. The metal mesh 710 is arranged to enclose the injection channels 228 and in some embodiments enclose the cooling channels 616. With the metal mesh 710, the plurality of spokes 210 may or may not include the coating layer 610.

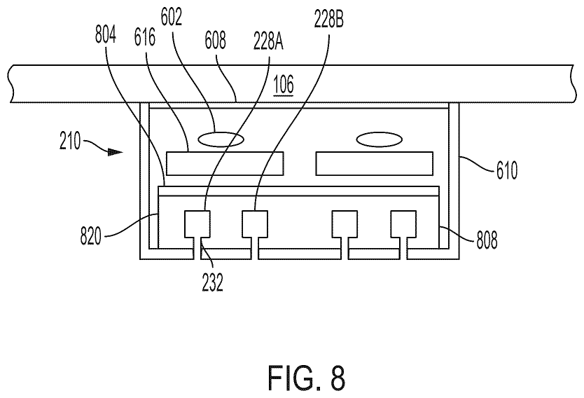

FIG. 8 depicts a schematic cross-sectional view of a spoke of the plurality of spokes 210 in accordance with at least some embodiments of the present disclosure. In some embodiments, as depicted in FIG. 8, each spoke of the plurality of spokes 210 comprises a body 620 made of metal and further comprises a ceramic body 820 disposed in the body 620 made of metal. Such an arrangement may be more cost effective than the body 620 made of ceramic, such as described with FIG. 7. The injection channel 228 and the plurality of gas outlets 232 are disposed in the ceramic body 820. In some embodiments, the body 620 has a recess 808 to accommodate the ceramic body 820. In some embodiments, the ceramic body 820 is bonded to the body 620 via a bond layer 804.

While the foregoing is directed to embodiments of the present disclosure, other and further embodiments of the disclosure may be devised without departing from the basic scope thereof.

1. Apparatus for use in a process chamber, comprising:
an annular body having one or more annular plenums disposed therein and an upper surface configured to be coupled to a lid of the process chamber;
a plurality of spokes extending radially inward from the annular body toward a central axis of the annular body; and
a plurality of gas outlets disposed along different radial locations of each spoke of the plurality of spokes, wherein the plurality of gas outlets are fluidly coupled to the one or more annular plenums.

2. The apparatus of claim 1, wherein each spoke of the plurality of spokes has an injection channel extending radially from the annular body toward the central axis and the plurality of gas outlets extend from the injection channel to a lower surface of each spoke.

3. The apparatus of claim 2, wherein the one or more annular plenums comprise a first plenum and a second plenum, wherein the injection channel includes a separation wall that defines an inner injection zone and an outer injection zone that is fluidly independent of the inner injection zone within each spoke, wherein the plurality of gas outlets disposed along the inner injection zone are fluidly coupled to the first plenum and the plurality of gas outlets disposed along the outer injection zone are fluidly coupled to the second plenum.

4. The apparatus of claim 1, further comprising a radical generation source coupled to the annular body, wherein the radical generation source is configured to generate radicals that are injected through at least some of the plurality of gas outlets.

5. The apparatus of claim 1, wherein the one or more annular plenums comprise two annular plenums that are separated by a divider wall, wherein an upper plenum of the two annular plenums is fluidly coupled to a first set of the plurality of spokes and a lower plenum of the two annular plenums is fluidly coupled to a second set of the plurality of spokes different than the first set.

6. The apparatus of claim 1, wherein the one or more annular plenums comprise four annular plenums associated with an inner gas injection zone, an outer gas injection zone, an inner radical injection zone, and an outer radical injection zone.

7. The apparatus of claim 1, wherein the plurality of spokes are uniformly spaced around the annular body.

8. The apparatus of claim 1, further comprising at least one of:
a heater disposed in the plurality of spokes; or
a cooling channel disposed in the plurality of spokes.

9. The apparatus of claim 1, wherein an outer surface of the plurality of spokes is coated with a ceramic material or is anodized.

10. The apparatus of claim 1, wherein the plurality of spokes have a circular or rectangular cross-sectional shape.

11. The apparatus of claim 1, wherein the plurality of spokes comprise a ceramic body and further comprising a metal mesh disposed in the ceramic body.

12. The apparatus of claim 1, wherein each spoke of the plurality of spokes comprises an aluminum body and further comprises a ceramic body disposed in the aluminum body, wherein each spoke includes an injection channel extending radially from the annular body toward the central axis, and wherein the injection channel and the plurality of gas outlets are disposed in the ceramic body.

13. The apparatus of claim 1, wherein the annular body includes an upper flange extending from an upper surface of the annular body and a lower flange extending from a lower surface of the annular body.

14. The apparatus of claim 1, wherein:
each spoke of the plurality of spokes includes one or more injection channels extending radially from the annular body toward the central axis and the plurality of gas outlets extend from the one or more injection channels to a lower surface of each spoke; and
the one or more annular plenums comprise two annular plenums that are separated by a divider wall, wherein an upper plenum of the two annular plenums is fluidly coupled to a first set of the plurality of spokes and a lower plenum of the two annular plenums is fluidly coupled to a second set of the plurality of spokes different than the first set; and
further comprising at least one of:
a heater disposed in the plurality of spokes; or
a cooling channel disposed in the plurality of spokes.

15. The apparatus of claim 14, wherein the one or more injection channels comprise a gas injection channel and a radical injection channel separate from the gas injection channel.

16. A process chamber, comprising:
a chamber body having sidewalls and a lid to define an interior volume therein, wherein the lid includes a central opening;
a substrate support for supporting a substate disposed in the interior volume; and
an apparatus disposed in the interior volume adjacent to the lid, the apparatus comprising:
an annular body having one or more annular plenums disposed therein and an upper surface configured to be coupled to a lid of the process chamber, wherein the annular body is made of a metal material and configured to form a faraday cage;
a plurality of spokes extending radially inward from the annular body toward a central axis of the annular body; and
a plurality of gas outlets disposed along different radial locations of each spoke of the plurality of spokes, wherein the plurality of gas outlets are fluidly coupled to the one or more annular plenums.

17. The process chamber of claim 16, wherein the process chamber is an inductively coupled plasma (ICP) chamber.

18. The process chamber of claim 16, further comprising a radical generation source coupled to the annular body, wherein the radical generation source is configured to generate radicals that are injected through at least one of the one or more annular plenums.

19. The process chamber of claim 16, wherein the one or more annular plenums comprise two annular plenums that are separated by a divider wall, wherein an upper plenum of the two annular plenums is fluidly coupled to a first set of the plurality of spokes and a lower plenum of the two annular plenums is fluidly coupled to a second set of the plurality of spokes different than the first set.

20. The process chamber of claim 16, wherein the plurality of spokes are in contact with the lid.
